(19) United States
(12) Patent Application Publication
(10) Pub. No.: US 2011/0091811 A1
(43) Pub. Date: Apr. 21, 2011

(54) DOUBLE-LAYERED PATTERNABLE ADHESIVE FILM, METHOD OF FORMING THE SAME, AND METHOD OF FORMING PATTERNABLE ADHESIVE LAYER USING THE SAME

(75) Inventors: Sun Jin SONG, Suwon-si (KR); Chul Ho JEONG, Gwangju (KR); Yong Seok HAN, Anyang-si (KR); Yi Yeol LYU, Yongin-si (KR)

(73) Assignee: SAMSUNG ELECTRONICS CO., LTD., Suwon-si (KR)

(21) Appl. No.: 12/757,229

(22) Filed: Apr. 9, 2010

(30) Foreign Application Priority Data
Oct. 16, 2009 (KR) 10-2009-0098967

(51) Int. Cl. G03F 7/20; B05D 1/36; H05K 3/00; H01L 21/46; G03C 1/00

(52) U.S. Cl. 430/271.1; 427/419.1; 427/97.1; 438/763; 430/325; 430/324; 257/E21.482

(57) ABSTRACT

A patternable adhesive film is formed in a double-layered structure of an adhesive layer having patternability and an adhesive layer having both adhesion and developability. Thus, the double-layered patternable adhesive film can effectively have both patternability and adhesion.

### CROSS-REFERENCE TO RELATED APPLICATION

This application claims priority to Korean Patent Application No. 10-2009-0098967, filed on Oct. 16, 2009, and all the benefits accruing there from under 35 U.S.C. §119, the content of which in its entirety is herein incorporated by reference.

### BACKGROUND

1. Field

The disclosure relates to a double-layered patternable adhesive film, a method of forming the same, and a method of forming a patternable adhesive layer using the same.

2. Description of the Related Art

Various packaging techniques for highly-integrated and high-capacity semiconductor devices have been developed, including use of an adhesive film to adhere a semiconductor device to a support.

Use of adhesive film is widespread in high-density semiconductor packages such as chip-sized packages, stack-type packages and system-in-packages because of the control of thicknesses or protrusions afforded when compared to, for example, a conventional paste-phase adhesive.

The use of an adhesive film to mount a semiconductor device requires that the film composition exhibit resistance to heat, dimensional stability, resistance to moisture, and low-temperature adhesion as well as adhesion at ambient and higher operating temperatures.

Techniques for interadhesion and interconnection of semiconductor devices by forming a pattern between semiconductor wafers or at an interface between semiconductor chips may in principle be used, where in order to accomplish such a technique, an adhesive film having both adhesion and patternability would be needed.

### SUMMARY

Thus, in an embodiment, a patternable adhesive film having both adhesion and patternability is disclosed.

In an exemplary embodiment, a double-layered patternable adhesive film includes: a first adhesive layer including a photocurable part containing a photocurable component (A); and a second adhesive layer disposed on a surface of the first adhesive layer and including a second thermosetting part containing a thermosetting component (B), and a developable part containing an alkali or organic solvent developable component (C).

The first adhesive layer may be formed to have an exposed surface, and the second adhesive layer may be formed to interface with an adherend.

The first adhesive layer may further include a first thermosetting part containing a thermosetting component, and the photocurable part may be included in a higher content than the first thermosetting part.

For example, the content of the photocurable part may be from about 30 wt % to about 95 wt % of the total weight of the first adhesive layer.

In the second adhesive layer, the content of the second thermosetting part may be higher than that of the developable part.

For example, the content of the second thermosetting part may be from about 20 wt % to about 95 wt % of the total weight of the second adhesive layer.

In an exemplary embodiment, the first adhesive layer may include a photocurable part containing a photocurable component (A) and an alkali or organic solvent developable component (C); a first thermosetting part containing a thermosetting component (B); and a binder part.

The second adhesive layer may include a second thermosetting part containing a thermosetting component (B); a developable part containing an alkali or organic solvent developable component (C) and a photocurable component (A); and a binder part.

The photocurable part containing the photocurable component (A) and the alkali or organic solvent developable component (C) may include a (meth)acrylate-based compound having an ethylenic unsaturated double bond. The second thermosetting part and the developable part are included in the form of an incorporated compound, i.e., a compound incorporating both the thermosetting part and the developable part, and, for example, an alkali or organic solvent developable thermosetting compound may be formed. The alkali or organic solvent developable thermosetting compound may be a multifunctional epoxy compound. Alternatively, the second thermosetting part and the developable part may be individually included, and the developable part may include a (meth)acrylate-based compound having a carboxyl or hydroxy group and an ethylenic unsaturated double bond. The binder part may include a (meth)acrylate-based compound having a carboxyl or hydroxy group and an ethylenic unsaturated double bond.

The first or second adhesive layer may further include at least one additive selected from the group consisting of a filler, a coupling agent, a coloring agent, an ion adsorbent, an antifoaming agent, a leveling agent, a thickening agent, and a flame retardant provided the inclusion of the additive does not significantly adversely affect the desired properties of the first or second adhesive layer(s).

In another embodiment, a method of forming a patterned adhesive film includes: forming a second adhesive layer, on a surface of a base film, by applying a second adhesive composition including (a) a thermosetting compound or an alkali or organic solvent developable thermosetting compound, (b) an alkali or organic solvent developable compound, (c) an organic solvent, and (d) at least one additive selected from the group consisting of a photocurable compound, a photoinitiator, a binder, a thermosetting agent, a thermosetting catalyst, a photoacid generator, and any combination thereof; and forming a first adhesive layer, on a surface of the second adhesive layer, by applying a first adhesive composition including (e) a photocurable composition, (f) an organic solvent, and (g) at least one additive selected from the group consisting of a thermosetting compound, a thermosetting agent, a thermosetting catalyst, a binder, a photoinitiator, a photoacid generator, and any combination thereof.

The first and/or second adhesive composition may further include (h) at least one additive selected from the group consisting of a filler, a coupling agent, a coloring agent, an ion adsorbent, an antifoaming agent, a leveling agent, a thickening agent, a flame retardant, and any combination thereof.

According to another embodiment, a method of forming a patternable adhesive layer includes: placing the double-layered patternable adhesive film on an adherend; forming a pattern by exposure and development; and performing thermal compression.

In another embodiment, a method of forming a patterned adhesive layer includes: forming a second adhesive layer on a surface of an adherend by applying a second adhesive composition including (a) a thermosetting compound or an alkali or organic solvent developable thermosetting compound, (b) an alkali or organic solvent developable compound, (c) an organic solvent, and (d) at least one additive selected from the group consisting of a photocurable compound, a photoinitiator, a binder, a thermosetting agent, a thermosetting catalyst, a photoacid generator, and any combination thereof; forming a first adhesive layer on a surface of the second adhesive layer by applying a first adhesive composition including (e) a photocurable compound, (f) an organic solvent, and (g) at least one additive selected from the group consisting of a thermosetting compound, a thermosetting agent, a thermosetting catalyst, a binder, a photoinitiator, a photoacid generator, and any combination thereof; forming a pattern by exposure and development; and performing thermal compression.

The adherend may be selected from the group consisting of a printed circuit board (“PCB”), a polyimide film, a polyethylene terephthalate (“PET”) film, a glass substrate, a ceramic substrate, a wafer, a semiconductor array, a semiconductor chip, and any combination thereof.

### BRIEF DESCRIPTION OF THE DRAWINGS

Exemplary embodiments are described in further detail below with reference to the accompanying drawings. It should be understood that various aspects of the drawings may have been exaggerated for clarity in which:

FIG. 1 is a cross-sectional view of a double-layered patternable adhesive film according to an exemplary embodiment; and

FIG. 2 is a schematic diagram illustrating a process of forming a double-layered patterned adhesive according to another exemplary embodiment.

### DETAILED DESCRIPTION

Various exemplary embodiments will now be described more fully with reference to the accompanying drawings in which some exemplary embodiments are shown. In the drawings, the thicknesses of layers and regions may be exaggerated for clarity.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, regions, integers, steps, operations, elements, and/or components, but do not preclude the presence or addition of one or more other features, regions, integers, steps, operations, elements, components, and/or groups thereof. All ranges and endpoints reciting the same feature are independently combinable.

It will be understood that when an element is referred to as being “on” another element, it can be directly on the other element or one or more intervening elements may be present. As used herein, the term “and/or” includes any and all combinations of one or more of the associated listed items.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

### I. Double-Layered Patternable Adhesive Film

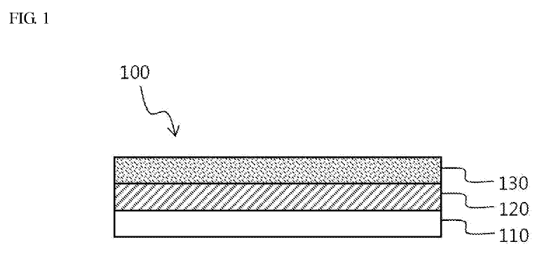

FIG. 1 is a schematic cross-sectional view of a double-layered patternable adhesive film according to an exemplary embodiment. Referring to FIG. 1, the double-layered patternable adhesive film 100 includes first and second adhesive layers (130 and 120), and a substrate or adherend 110.

In the double-layered adhesive film exemplified in FIG. 1, the first adhesive layer 130 includes a photocurable part containing a photocurable component (A). The second adhesive layer 120 includes a second thermosetting part containing a thermosetting component (B), and a developable part containing an alkali or organic solvent developable component (C).

The first and second adhesive layers 130 and 120 respectively may be formed on a base film 110. Here, the first adhesive layer 130 may be formed to have an exposed surface, and the second adhesive layer 120 may be formed on a surface of the base film or an adherend. The first adhesive layer 130 may in this way be formed on a surface of the second adhesive layer 120.

Since the first adhesive layer 130 contains a relatively large amount of the photocurable component (A), the first surface layer 130 has greater patternability (i.e., higher resolution, greater depth of focus, and the like) relative to the second adhesive layer 120. The second adhesive layer 120 contains a relatively large amount of the thermosetting component (B), and thus it has greater adhesion to a substrate or adherend relative to the composition of the first adhesive layer 130. Moreover, the second adhesive layer 120 is disposed under the first adhesive layer 130, and is not directly exposed to a developing solvent or developer (e.g., basic developer such as those based on aqueous sodium hydroxide or tetramethylammonium hydroxide) during developing to form a pattern. As a result, any loss of the low-molecular weight thermosetting component due to the action of the developing solvent or developer can be significantly reduced.

Such a double-layered structure in the patternable adhesion layer can provide both improved patternability and adhesion and can be useful in a process requiring both of these properties. The double-layered patternable adhesive film can thus be used for a process requiring adhesion by forming a pattern by sequential exposure and development, followed by performing thermal compression.

For example, the double-layered adhesive film may be applied to three-dimensional high-density packaging technology such as wafer-level packaging (“WLP”) or through-silicon via packaging. The through-silicon via technology involves forming a vertical electrical connection (a “via”) in a silicon wafer, and filling the through-via with high electrical conducting material such as copper to connect integrated chips each other. For the through-silicon via, the adhesive film between the wafers should have patternability to connect the through-silicon via, and high adhesion to adhere the wafers each other.

Unlike the double-layered adhesive films disclosed herein, in a single-layered adhesive film formed of a mixture of a photocurable component (A) which is patternable with a thermosetting component (B), the low molecular weight thermosetting component (B), which is adhesive, is likely to dissolve during development of the single layer adhesive film to form a pattern. Accordingly, the adhesive film can easily lose most of its adhesive properties. Furthermore, if the content of the photocurable component (A) is increased to improve patternability, the adhesion can be further degraded, and if the content of the thermosetting component (B) is increased in an effort to improve the adhesion, pattern formation and resolution in the adhesive film become difficult to achieve.

For this reason, the exemplary embodiment provides the double-layered patternable adhesive film.

Hereinafter, each layer of the double-layered patternable adhesive film will be described in further detail.

### First Adhesive Layer

The first adhesive layer 130 includes a photocurable part containing a photocurable component (A). The first adhesive layer 130 can therefore make a pattern by exposure to an actinic radiation (e.g., broad band UV, 436 nm (g-line) UV, 365 nm (i-line) UV, 248 nm UV (DUV), e-beam, and the like) because of the photoreactivity and photocurability of the adhesive layer. Here, the term “photocurable component (A)” refers to a component which reacts and/or is cured by exposure to (i.e., irradiation with) light such as UV, or by electron beam.

To increase the patternability, the photocurable part may contain the photocurable component (A) and an alkali or organic solvent developable component (C). Here, the term “alkali or organic solvent developable component” refers to a component which can be dissolved in a developing solution such as an alkali aqueous solution or organic solvent.

In another example, the first adhesive layer 130 may further include a first thermosetting part containing a thermosetting component (B) to impart adhesion. Here, the term “thermosetting component” refers to a component which reacts when exposed to and/or is cured by heat. As described above, when the first adhesive layer 130 includes the thermosetting part, a pattern is formed on the adhesive layer, and also a plurality of adherends which need to be adhered to each other either directly or indirectly can be effectively adhered to the first adhesive layer 130.

Here, the content of the photocurable part in the first adhesive layer 130 may be higher than that of the first thermosetting part. The content of the photocurable part may be 100 or more parts by weight based on 100 parts by weight of the first thermosetting part.

Alternatively, the content of the photocurable part may be 30 to 95 wt % of the total weight of the first adhesive layer 130. When the content of the photocurable part is 30 wt % or more, the first adhesive layer 130 may have higher patternability as well as adhesion relative to either a single layer adhesive film or to the second adhesive layer 120. However, when an excessive amount of the photocurable part is included in the first adhesive layer 130, it can become difficult to dry the layer after coating to remove solvent, and hence shrinkage of the film increases, and film characteristics (dimensional stability, patternability, and the like) can degrade.

The first adhesive layer 130 may further include a binder part as necessary. The binder part may contain a coupling component (D) to be coupled with the above-described components of the photocurable part. The binder part may further contain a photocurable component (A) and/or an alkali or organic solvent developable component (C) to further increase photocurability and/or developability during patterning.

A thickness of the first adhesive layer 130 is not particularly limited, and may correspond to a desired thickness of a patterned layer. For example, the thickness of the first adhesive layer may from about 50 nm to about 100 micrometers (μm).

In one example, the first adhesive layer 130 may include a photocurable part containing a photocurable component (A), and a first thermosetting part containing a thermosetting component (B).

In another example, the first adhesive layer 130 may include a photocurable part containing a photocurable component (A) and an alkali or organic solvent developable component (C), and a first thermosetting part containing a thermosetting component.

In still another example, the first adhesive layer 130 may include a photocurable part containing a photocurable component (A) and an alkali or organic solvent developable component (C), a first thermosetting part containing a thermosetting component (B), and a binder part.

In yet another example, the first adhesive layer 130 may include a photocurable part containing a photocurable component (A) and an alkali or organic solvent developable component (C), a first thermosetting part containing a thermosetting component (B), a binder part, and at least one additive selected from the group consisting of a filler, a coloring agent, an antifoaming agent, a leveling agent, a coupling agent, an ion adsorbent, a flame retardant, and any combination thereof.

### Second Adhesive Layer

The second adhesive layer 120 includes a second thermosetting part and a developable part. The second thermosetting part contains a thermosetting component (B), and the developable part contains an alkali or organic solvent developable component (C). Such a second adhesive layer 120 can have high adhesion to a substrate or adherend relative to either a single adhesive layer or the first adhesive layer 130 because of the thermosettability imparted by the thermosetting compound (B), and also have patternability since the developable part provides solubility in a developing solution such as an alkali aqueous solution or organic solvent.

The second adhesive layer 120 includes both components having thermosettability and developability. Here, the second adhesive layer 120 may include the second thermosetting part and the developable part as separate parts, or may include thermosetting and developable parts incorporated into a composite part, referred to herein as an incorporated compound. As an example of the former, the second adhesive layer 120 may include a second thermosetting part formed of a compound containing a thermosetting component (B) and a separate developable part formed of a compound containing an alkali or organic solvent developable component (C). As an example of the latter, the second adhesive layer 120 may contain a compound containing both a thermosetting component (B) and an alkali or organic solvent developable component (C), e.g., an alkali or organic solvent developable thermosetting compound (hereinafter, referred to as a “developable thermosetting compound”).

In the second adhesive layer 120, the content of the second thermosetting part may be higher than that of the developable part. The content of the second thermosetting part may be 100 or more parts by weight based on 100 parts by weight of the developable part.

Alternatively, the content of the second thermosetting part may be 20 to 95 wt % or in a further example, 30 to 95 wt % of the total weight of the second adhesive layer. When the content of the thermosetting part is 20 wt % or more, the second adhesive layer 120 has excellent adhesion to a substrate or adherend because a large amount of the thermosetting part remains after development, sufficient to provide the desired adhesion. However, when an excessive amount of the thermosetting part is included, film formation and patterning may be undesirably adversely affected where for example, coating defects may occur, and the second adhesive layer 120 may have insufficient developability during patterning, or the like.

The second thermosetting part may contain a photocurable component (A), in addition to the thermosetting component (B). The developable part may also include a photocurable component (A), in addition to the alkali or organic solvent developable component (C).

The photocurable component (A) may be combined with the thermosetting component (B) or the alkali or organic solvent developable component (C), or individually contained. As an example of the former, the second adhesive layer 120 may include a resin having both a thermosetting component (B) and a photocurable component (A), e.g., a photocurable thermosetting resin or a resin prepared by combining a thermosetting compound with a photocurable monomer. As an example of the latter, the second adhesive layer 120 may include a mixture of a thermosetting resin with a photocurable resin.

Like the first adhesive layer 130, the second adhesive layer 120 may further include a binder part as necessary. The binder part may contain a coupling component (D) to be coupled with the above-described thermosetting part and developable part. The binder part may also contain a photocurable component (A) and/or an alkali or organic solvent developable component (C) to have photocurability and/or developability during patterning.

In one example, the second adhesive layer 120 may include a developable thermosetting compound in which a second thermosetting part containing a thermosetting component (B) and a developable part containing an alkali or organic solvent developable component (C) are included in the form of an incorporated compound.

In another example, the second adhesive layer 120 may include a second thermosetting part containing a thermosetting component (B) and a photocurable component (A); and a developable part containing an alkali or organic solvent developable component (C) and a photocurable component (A).

In still another example, the second adhesive layer 120 may include a second thermosetting part containing a thermosetting component (B) and a photocurable component (A); a developable part containing an alkali or organic solvent developable component (C) and a photocurable component (A), and a binder part.

In yet another example, the second adhesive layer 120 may include a second thermosetting part containing a thermosetting component (B) and a photocurable component (A), a developable part containing an alkali or organic solvent developable component (C) and a photocurable component (A), a binder part, and at least one additive selected from the group consisting of a filler, a coloring agent, an antifoaming agent, a leveling agent, a coupling agent, an ion adsorbent, a flame retardant, and any combination thereof.

Individual components constituting each layer will be described in further detail below.

### (1) Photocurable Part

The photocurable part contains a photocurable component (A). The photocurable component (A) may be a photocurable compound having a radical polymerizable unsaturated double bond, e.g., an ethylenic unsaturated double bond.

The photocurable part may further contain an alkali or organic solvent developable component (C). An example of the alkali or organic solvent developable component (C) may include a compound containing a carboxyl or hydroxy group.

The alkali or organic solvent developable component (C) may be combined with a photocurable component (A) or individually contained. Thus, the photocurable part may contain a compound including both the photocurable component (A) and the alkali or organic solvent developable component (C), or a mixture of a photocurable compound with an alkali developable compound. The alkali or organic solvent developable component (C) will be described in detail below in (3).

The photocurable part, for example, may contain a precursor containing a hydroxy or carboxyl group which is soluble in an alkali aqueous solution or organic solvent, a photocurable compound having an ethylenic unsaturated double bond, or a resin prepared by combining at least two of these groups. The photocurable part may contain a resin prepared by combining a photocurable compound having an ethylenic unsaturated double bond with a compound containing a hydroxy or carboxyl group, which is soluble in an alkali aqueous solution or organic solvent.

Examples of the photocurable compound may include one or a combination of at least two selected from the group consisting of: (meth)acrylates containing a hydroxy group such as 2-hydroxyethyl (meth)acrylate, 2-hydroxypropyl (meth)acrylate, pentaerythritol tri(meth)acrylate, and dipentaerythritol penta(meth)acrylate; aqueous-soluble (meth)acrylates such as polyethyleneglycol di(meth)acrylate and polypropyleneglycol di(meth)acrylate; multifunctional polyester (meth)acrylates of polyols such as trimethylolpropane tri(meth)acrylate, pentaerythritol tetra(meth)acrylate, and dipentaerythritol hexa(meth)acrylate; (meth)acrylates of multifunctional alcohols or bisphenol A such as trimethylolpropane and hydrogen-added bisphenol A, and ethylene oxide and/or propylene oxide additions of polyphenols such as biphenol; multifunctional or monofunctional polyurethane (meth)acrylates which are isocyanate-modified products of the (meth)acrylates containing a hydroxy group; epoxy(meth)acrylates which are (meth)acrylate additions of bisphenol A diglycidyl ether, hydrogen-added bisphenol A diglycidyl ether or phenol novolac epoxy resin; caprolactone-modified (meth)acrylates such as caprolactone-modified di(trimethylolpropane) tetra(meth)acrylate, (meth)acrylates of e-caprolactone-modified dipentaerythritol, and caprolactone-modified hydroxypivalic acid neopentylglycolester di(meth)acrylate; and any combination thereof. Here, the term “(meth)acrylate” refers to acrylate, methacrylate or a mixture thereof, which is applied to similar expressions in the same manners.

The photocurable part may contain a (meth)acrylate compound having an ethylenic unsaturated double bond and a carboxyl or hydroxy group (hereinafter, referred to as a “photosensitive (meth)acrylate compound”). Since the photosensitive (meth)acrylate compound contains both a photocurable component (A) and an alkali or organic solvent developable component (C), it can provide photocurability to the adhesive layer and allows the adhesive layer to be dissolved in a developing solution, to form a pattern.

Examples of the photosensitive (meth)acrylate compound may include, but are not limited to, methyl(meth)acrylate, ethyl(meth)acrylate, butyl(meth)acrylate, isobutyl(meth)acrylate, 2-ethylhexyl(meth)acrylate, isooctyl(meth)acrylate, glycidyl(meth)acrylate, cyclohexyl(meth)acrylate, isobornyl(meth)acrylate, benzyl(meth)acrylate, 2-hydroxy(meth)acrylate, trimethoxybutyl(meth)acrylate, ethylcarbitol(meth)acrylate, phenoxyethyl(meth)acrylate, 2-hydroxyethyl(meth)acrylate, trimethylolpropane tri(meth)acrylate, tetramethylolmethane tetra(meth)acrylate, pentaerythritol hexa(meth)acrylate, pentaerythritol tetra(meth)acrylate, dipentadierythritolmonohydroxy penta(meth)acrylate, dipentaerythritol hexa(meth)acrylate, 1,4-butylglycol di(meth)acrylate, 1,6-hexanediol di(meth)acrylate, polyethyleneglycol di(meth)acrylate, oligoester (meth)acrylate, multifunctional urethane (meth)acrylate, urea (meth)acrylate, and any combination thereof. Further, the photosensitive (meth)acrylate compound may be a combination of at least two of the above-described examples.

### (2) Thermosetting Part

The thermosetting part contains a thermosetting component (B). The thermosetting component (B) may be a common thermosetting resin or a resin cured by a ring-opening polymerization mechanism.

The thermosetting part may further contain a photocurable component (A). The photocurable component (A) is the same as described in (1). The photocurable component (A) and the thermosetting component (B) are included separately or as incorporated into a combined form (i.e., as an incorporated compound). Thus, the thermosetting part may include a compound containing both the thermosetting component (B) and the photocurable component (A). Such a thermosetting part may include a photocurable thermosetting resin having both thermosettability and photocurability. The thermosetting part may include a mixture of a thermosetting compound with a photocurable compound.

The thermosetting compound may be one or a combination of at least two selected from the group consisting of an epoxy resin, a cyanate resin, a bismaleimide resin, a phenol resin, a benzoxazine resin, a urea resin, a melamine resin, an alkyd resin, an acryl resin, an unsaturated polyester resin, a diallyl phthalate resin, a silicone resin, a resorcinol-formaldehyde resin, a xylene resin, a furan resin, a polyurethane resin, a ketone resin, a triallylcyanate resin, a polyisocyanate resin, a resin containing tri(2-hydroxyethyl) isocyanate, a resin containing triallyltrimellitate, a thermosetting resin synthesized from cyclopentadiene, a thermosetting resin prepared by trimerization of aromatic dicyanamide, and any combination thereof.

In the second adhesive layer, both the thermosetting part and the developable part may be included, and specifically, may be included as separate compounds. Here, the thermosetting compound may be a compound capable of reacting with the developable part. For example, the thermosetting compound may include a component (E) that can thermally react with a carboxyl and/or hydroxy group contained in the alkali or organic solvent developing component (C), in addition to the thermosetting component (B). Examples of the component (E) may include, but are not limited to, thermosetting compounds having as functional groups, amino, isocyanate, oxazoline, carbodiimide, epoxy, and any combination thereof.

As described above, in the second adhesive layer 120, the thermosetting part and the developable part may be included in the form of incorporated compound, i.e., incorporated into a single molecular compound as discussed above.

Here, the second adhesive layer 120 may include a compound containing both the thermosetting component (B) and the alkali or organic solvent developable component (C). For example, the second adhesive layer 120 may include a developable thermosetting compound.

The developable thermosetting compound may be a thermosetting resin having at least two cyclic ether and/or thioether groups (hereinafter, referred to as “(thio)ether groups”).

The thermosetting resin having at least two cyclic (thio)ether groups in one molecule may be a multifunctional epoxy compound having at least two epoxy groups in one molecule, a multifunctional oxetane compound having at least two oxetanyl groups in one molecule, or an episulfide resin having at least two (thio)ether groups in one molecule.

The multifunctional epoxy resin may be one or a combination of at least two selected from the group consisting of a bisphenol A epoxy resin, a brominated epoxy resin, a hydrogen-added bisphenol A epoxy resin, a brominated bisphenol A epoxy resin, a bisphenol F epoxy resin, a bisphenol S epoxy resin, a novolac epoxy resin, a phenol novolac epoxy resin, a cresol novolac epoxy resin, an N-glycidyl epoxy resin, a novolac epoxy resin of bisphenol A, a bixylenol epoxy resin, a biphenol epoxy resin, a chelate-type epoxy resin, a glyoxal epoxy resin, an epoxy resin containing an amino group, a rubber-modified epoxy resin, a dicyclopentadiene phenolic epoxy resin, a diglycidylphthalate resin, a glycidyl amine epoxy resin, a heterocyclic epoxy resin, a tetraglycidyl xylenoylethane resin, an alicyclic epoxy resin, a trihydroxyphenylmethane epoxy resin, a tetraphenylolethane epoxy resin, an epoxy resin containing a naphthalene group, a silicon-modified epoxy resin, an ε-caprolactone-modified epoxy resin, and any combination thereof. To provide a flame-retardant characteristic, an atom such as phosphorus may be introduced to a structure of the multifunctional epoxy resin. For example, a phosphate group may be included. These epoxy resins are thermally cured, thereby providing improved cohesion, resistance to soldering heat, and resistance to electroless plating after curing to the adhesive layer.

The epoxy resin may be present in a solid phase or semi-solid phase at room temperature, and inflammable or flame-retardant in a diluent (a liquid-phase photopolymerizable compound or organic solvent at room temperature). Where such an epoxy resin is used, the solid-phase or semi-solid-phase epoxy resin is dispersed as a particulate in a pre-cured composition. For this reason, the composition has a longer available time, and thus is easy to handle.

The epoxy resin present in the solid or semi-solid phase at room temperature may be a bisphenol S epoxy resin, a phenol novolac epoxy resin, a diglycidylphthalate resin, a heterocyclic epoxy resin, a bixylenol epoxy resin, a biphenyl epoxy resin, a tetraglycidylxylenoylethane resin, or any combination thereof.

Examples of the multifunctional oxetane compound may include multifunctional oxetanes such as bis[(3-methyl-3-oxetanylmethoxy)methyl]ether, bis[(3-ethyl-3-oxetanylmethoxy)methyl]ether, 1,4-bis[(3-methyl-3-oxetanylmethoxy)methyl]benzene, 1,4-bis[(3-ethyl-3-oxetanylmethoxy)methyl]benzene, (3-methyl-3-oxetanyl)methylacrylate, (3-ethyl-3-oxetanyl)methylacrylate, (3-methyl-3-oxetanyl)methylmethacrylate, (3-ethyl-3-oxetanyl)methylmethacrylate, and oligomers and copolymers thereof; and esters produced by esterification of oxetane alcohols with resins having a hydroxy group such as novolac resins, poly(p-hydroxystyrene), cardo bisphenols, calixarenes, calixresorcinarenes, or silsesquioxane. The multifunctional oxetane compound may also include a copolymer of an unsaturated monomer having an oxetane ring and alkyl(meth)acrylate.

Examples of the compound having at least two cyclic thioether groups in one molecule may include a bisphenol A episulfide resin, YL7000, commercially available from Japan Epoxy Resin Co. The compound may also include an episulfide resin prepared by replacing an oxygen atom on an epoxy group of a novolac epoxy resin with a sulfur atom.

In the thermosetting component having at least two cyclic (thio)ether groups in one molecule, the content of the cyclic (thio)ether groups may be 0.6 to 2.5 equivalent weight or in a further example, 0.8 to 2.0 equivalent weight based on 1 equivalent weight of the carboxyl group of the photosensitive component. When the equivalent weight of the thermosetting component having at least two cyclic (thio)ether groups in one molecule is less than 0.6 equivalent weight, the carboxyl groups remain on the cured coating layer, leading to degradation in resistance to heat, alkali, and electric insulating capability. When the equivalent weight of the thermosetting component having at least two cyclic (thio)ether groups in one molecule is more than 2.5 equivalent weight, the cyclic (thio)ether groups with a low molecular weight may remain on the dried coating layer, leading to reduction in hardness of the coating layer.

### (3) Developable Part

The developable part contains an alkali or organic solvent developable component (C). Here, the term “developability” refers to performance of a site which is chemically converted by irradiation with light to be insoluble or soluble in an alkali aqueous solution or organic solvent. Such an alkali or organic solvent developable component (C) is developable after exposure to light, and thereby forms a pattern.

The alkali or organic solvent developable component (C) may be a resin containing a carboxyl, hydroxy, or aromatic hydroxy group, which is soluble in an alkali or organic solvent developing solution. Such an alkali or organic solvent developable component (C) can have improved patternability in an alkali or organic solvent developing solution.

The compound containing the alkali or organic solvent developable component (C) may include at least one selected from the group consisting of a polyimide resin, a polyamide resin, a polyamideimide resin, a polyetherimide resin, a polyurethaneimide resin, a polyurethaneamideimide resin, a siloxane polyimide resin, a polyesterimide resin, a copolymer thereof, a precursor thereof (e.g., a polyamic acid), a polybenzoxanol resin, a phenoxy resin, a phenol novolac resin, a polyethersulfone resin, a polyphenylene sulfide resin, a polyester resin, a poly ether ketone resin, a (meth)acryl copolymer, and any combination thereof.

Meanwhile, like the developable thermosetting compound described in (2), the developable part and the thermosetting part may be included in the form of an incorporated compound including the developable part and the thermosetting part.

In one example, the developable part may include a resin that does not have an ethylenic unsaturated double bond, which is referred to as a “resin containing a developable component (C)” in some cases. Alternatively, the developable part may include a photocurable resin having an ethylenic unsaturated double bond, which is referred to as a “photocurable resin containing a developable component (C)” in some cases.

The resin containing the developable component (C) may include one of the following compounds:

\textcircled{1} a resin containing a carboxyl group obtained by copolymerization of an unsaturated carboxylic acid or derivative (a) such as a (meth)acrylate with a compound (b) having an unsaturated double bond such as styrene, α-methyl styrene, lower alkyl (i.e., having 1 to 4 carbon atoms) (meth)acrylate, or isobutylene;

\textcircled{2} a resin containing a carboxyl group obtained by reacting a saturated or unsaturated polybasic acid anhydride (d) with a secondary hydroxy group of a product which is obtained by reacting an organic acid (i) that has one carboxyl group in one molecule, but does not have an ethylenic unsaturated bond, such as alkyl carboxylic acid having 2 to 17 carbon atoms or alkyl carboxylic acid containing an aromatic group, with an epoxy group of a copolymer of the compound (b) having an unsaturated double bond, and glycidyl(meth)acrylate;

\textcircled{3} a urethane resin containing a carboxyl group obtained by polyaddition of a diisocyanate (j) such as an aliphatic diisocyanate, branched aliphatic diisocyanate, alicyclic diisocyanate, or aromatic diisocyanate; a dialcohol compound (k) containing a carboxyl group such as dimethylolpropionic acid and dimethylolbutanoic acid; and a diol compound (m) such as polycarbonate polyol, polyether polyol, polyester polyol, polyolefin polyol, acrylic polyol, and a compound containing a phenolic or alcohol hydroxy group;

\textcircled{4} a photosensitive resin containing a carboxyl acid obtained by reacting a saturated or unsaturated polybasic acid anhydride (d) with a primary hydroxy group of a modified oxetane compound which is obtained by reacting an unsaturated monocarboxylic acid (h) with a multifunctional oxetane compound having at least two oxetane rings in one molecule;

\textcircled{5} a polyester resin containing a carboxyl acid obtained by adding a saturated or unsaturated polybasic acid anhydride (d) to a primary hydroxy group of a product which is obtained by reacting dicarboxylic acid with a bifunctional epoxy or oxetane resin; or any combination thereof.

The photocurable resin containing the developable component (C) may also be one of the following compounds having photocurability, which include:

\textcircled{6} a photosensitive resin containing a carboxyl group obtained by adding an ethylenic unsaturated group as a pendant to a product which is obtained by reacting a compound containing an ethylenic unsaturated group such as a vinyl, allyl, or (meth)acryloyl group and a reactive group such as an epoxy or acid chloride, e.g., glycidyl(meth)acrylate, with a part of a copolymer of an unsaturated carboxylic acid (a) and a compound (b) having an unsaturated double bond;

\textcircled{7} a photosensitive resin containing a carboxyl group obtained by reacting a saturated or unsaturated polybasic acid anhydride (d) such as phthalic acid anhydride, tetrahydrophthalic acid anhydride, or hexahydrophthalic acid anhydride with a secondary hydroxy group of a product which is obtained by reacting an unsaturated carboxylic acid (a) with a copolymer of a compound (c) having an unsaturated double bond and an epoxy group such as glycidyl(meth)acrylate or α-methylglycidyl(meth)acrylate and a compound (b) having an unsaturated double bond;

\textcircled{8} a photosensitive resin containing a carboxyl group obtained by reacting a copolymer of an acid anhydride (e) having an unsaturated double bond such as maleic acid anhydride or itaconic acid and a compound (b) having an unsaturated double bond with a compound (f) having one hydroxy group and at least one ethylenic unsaturated double bond such as a hydroxyalkyl(meth)acrylate;

\textcircled{9} a photosensitive compound (resin) containing a carboxyl group obtained by reacting a saturated or unsaturated polybasic acid anhydride (d) with a hydroxy group of an ester which is obtained by (total or partial) esterification of a carboxyl group of an unsaturated monocarboxylic acid (h) such as (meth)acrylic acid with an epoxy group of a multifunctional epoxy compound (g) having at least two epoxy groups in one molecule or a multifunctional epoxy resin, in which a hydroxy group is further epoxidized with epichlorohydrin;

\textcircled{10} a photosensitive urethane resin containing a carboxyl group obtained by polyaddition of diisocyanate (j), a (meth)acrylate of a bifunctional epoxy resin or a partial acid anhydride modified product thereof (n) such as a bisphenol A epoxy resin, a hydrogenated bisphenol A epoxy resin, a brominated bisphenol A epoxy resin, a bisphenol F epoxy resin, a bisphenol S epoxy resin, a bixylenol epoxy resin, or a biphenol epoxy resin, a dialcohol compound containing a carboxyl group (k), and a diol compound (m);

\textcircled{11} a urethane resin containing a carboxyl group to which an unsaturated double bond is introduced at a terminal by adding a compound (f) having one hydroxy group and at least one ethylenic unsaturated double bond such as a hydroxyalkyl(meth)acrylate upon synthesis of resin \textcircled{2} or \textcircled{10};

\textcircled{12} a urethane resin containing a carboxyl group which has a (meth)acrylated terminal group by adding a compound having one isocyanate group and at least one (meth)acryloyl group in one molecule of a product obtained by reacting equivalent moles of isophorone diisocyanate with pentaerythritol tri(meth)acrylate upon synthesis of resin \textcircled{2} or \textcircled{10};

\textcircled{13} a photosensitive resin containing a carboxyl group obtained by introducing an unsaturated double bond to a product obtained by reacting a bisepoxy compound with bisphenols, and reacting with a saturated or unsaturated polybasic acid anhydride (d); and

\textcircled{14} a photosensitive resin containing a carboxyl group obtained by reacting a saturated or unsaturated polybasic acid anhydride (d) with a product which is obtained by reacting an unsaturated monocarboxylic acid (h) with a product obtained by reacting a novolac phenol resin with alkyleneoxide such as ethylene oxide, propylene oxide, butylene oxide, trimethylene oxide, tetrahydrofuran, or tetrahydropyran and/or a cyclic carbonate such as ethylenecarbonate, propylenecarbonate, butylenecarbonate or 2,3-carbonatepropylenemethacrylate, or a combination thereof.

For example, since the developable part containing a carboxyl or hydroxy group has a plurality of free carboxyl or hydroxy groups on a side chain of the polymer backbone, developing can be carried out in a developing solution.

As the alkali or organic solvent developable component (C), the resin containing a carboxyl or hydroxy group may have an acid value (sometimes referred to in the art as “acid number”) of from 40 to 200 mgKOH/g. When the acid value of the resin is less than 40 mgKOH/g, developing becomes difficult to perform due to low solubility of the developable component in the developer (i.e., alkali developer), whereas where the acid value of the resin is more than 200 mgKOH/g, the exposed part (i.e., the crosslinked part where the adhesive layer is developable in negative tone) or the unexposed part (i.e., where the adhesive layer is developable in positive tone) is dissolved in a developing solution so that the pattern after developing becomes excessively thin (i.e., has a high film thickness loss and reduced contrast), or the exposed part and non-exposed part each dissolve by undercut, leading to delamination. Thus, it can be difficult to form a pattern.

Such a resin containing the developable component (C) or a photosensitive resin containing the developable component (C) may be included in an amount of 20 to 70 wt % or in a further example, 30 to 60 wt % based on the weight of the total composition. When the content of this resin is below 20 wt %, the hardness of the adhesive layer may be degraded, and when the content of this resin exceeds the above range, the viscosity of composition may increase or spreading may be difficult.

### (4) Binder Part

The binder part may be included in both the first and second adhesive layers. The binder part may contain a coupling component (D) to be coupled with the above-described components of the photocurable or thermosetting part. The binder part may also contain a photocurable component (A) to have photocurability during patterning. The binder part may also contain an alkali or organic solvent developable component (C), which is called a developable binder part. Such a developable binder part may be formed of the resin containing the developable component (C) or the photocurable resin containing the developable component (C), which is described in (3). The photocurable component (A) and the developable component (C) are the same as described above.

In one example, the binder part may include a binder containing a photocurable branched acrylate and a silane-based functional group. The binder may have a glass transition temperature (Tg) of −20 to 60° C., and a weight average molecular weight of 10,000 to 1,000,000 g/mol or in a further example, 20,000 to 500,000 g/mol.

Examples of the binder may include a polyester binder, a polyurethane binder, a polysilicon binder, a natural rubber binder, an acrylic binder, and any combination thereof. Among them, the acrylic binder has various function groups which are introduced to a side chain and excellent film formability.

### (5) Additives

The first or second adhesive layer 130 or 120 may further include at least one additive selected from the group consisting of a filler, a coupling agent, a coloring agent, an ion adsorbent, an antifoaming agent, a leveling agent, a thickening agent, a flame retardant, and any combination thereof.

### Filler

An organic or inorganic filler may be used to prevent shrinkage of the adhesive layer during curing and improve cohesion and hardness.

For example, the inorganic filler may be one or a combination of at least two selected from barium sulfate, barium titanate, amorphous silica, crystalline silica, fused silica, silica sphere, talc, clay, magnesium carbonate, calcium carbonate, aluminum oxide, aluminum hydroxide, mica, boron nitride, titanium dioxide, glass, iron oxide, aluminum borate, ceramic, and any combination thereof.

### Coupling Agent

A coupling agent may be used to increase adhesion. For example, the coupling agent may be a silane-, titanium- or aluminum-based coupling agent. Among them, a silane-based coupling agent such as an imidazole-, thiazole- or triazole-based coupling agent may be used because of high adhesion.

### Coloring Agent

A coloring agent may be added as necessary. The coloring agent may be a red, blue, green or yellow coloring agent, which is well known in the art, such as phthalocyanine blue, phthalocyanine green, iodine green, diazo yellow, crystal violet, titanium oxide, carbon black, naphthalene black, or any combination thereof. The coloring agent may be a pigment, dye or coloring matter.

### Ion Adsorbent

When impurity ions such as alkali metal ions, alkali earth metal ions, halogen ions, particularly, chloride ions or hydrolytic chloride, are present in a compound, electromigration or corrosion on a metal conductor circuit may occur. To prevent this, the ion adsorbent may be used to adsorb these ions.

Such an ion adsorbent may be a compound such as a triazine thiol compound or bisphenol reducing agent, which is known to prevent ionization and dissolution of copper (Cu). In addition, an inorganic ion adsorbent such as zirconium, antimony-bismuth or magnesium-aluminum compound may be also used as the ion adsorbent.

### Others

As necessary, a well-known additive, for example, a thickening agent such as fine silica, organic bentonite, or montmorillonite, a silicon-, fluorine- or polymer-based antifoaming agent, a leveling agent, a phosphorus- or antimony-based flame retardant, or any combination thereof, may be added.

### Base Film

Various polymer films may be used as the base film 110. Examples of the polymer film may include polyolefin films such as polyethylene, polypropylene, polystyrene, ethylene/propylene copolymer, poly-1-butene, ethylene/vinyl acetate copolymer, polyethylene/styrene butadiene rubber mixture, and polyvinylchloride films; polyester films such as a polyethylene terephthalate film; polymer films such as polycarbonate and poly(methylmethacrylate) films; thermoplastic elastomer films such as polyurethane, polyimide, polyamideimide, and polyamide-polyol copolymer films; and any combination thereof. The base film 110 may have a single- or double-layered structure. The base film 110 may be treated to have release properties such that it is readily delaminated and in this way adhesive films may be formed on a surface of an adherend.

A thickness of the base film 110 is not particularly limited, and generally ranges from 0.1 to 150 μm or in a further example, 0.5 to 100 μm.

### II. Method of Forming Patternable Film

A method of forming the double-layered patternable adhesive film, which has been described, is provided.

According to an exemplary embodiment, the double-layered patternable adhesive film may be formed by sequentially applying a second adhesive composition and a first adhesive composition onto a surface of a base film, and thus a laminated structure of a base film, a second adhesive layer and a first adhesive layer is formed.

Alternatively, the double-layered patternable adhesive film may be formed by in turn forming individual adhesive films to which second and first adhesive compositions are respectively applied, and coupling the adhesive films with each other. Here, the double-layered patternable adhesive film may be formed in a laminated structure of sequential adjacent layers having removable protective base films having the structure of a second base film, a second adhesive layer, a first adhesive layer, and a first base film. The base films can be delaminated from the double-layered patternable adhesive film to allow the adhesive film to be disposed on an adherend.

In an example, the double-layered patternable adhesive film may be formed by a method including the following operations:
forming a second adhesive layer on a base film by applying a second adhesive composition containing (a) a thermosetting compound or an alkali or organic solvent developable thermosetting compound, (b) an alkali or organic solvent developable compound, (c) an organic solvent, and (d) at least one additive selected from the group consisting of a photocurable compound, a photoinitiator, a binder, a thermosetting agent, a thermosetting catalyst, a photoacid generator, and any combination thereof; and
forming a first adhesive layer on the second adhesive layer by applying a first adhesive composition containing (e) a photocurable compound, (f) an organic solvent, and (g) at least one additive selected from the group consisting of a thermosetting compound, a thermosetting agent, a thermosetting catalyst, a binder, a photoinitiator, a photoacid generator, and any combination thereof.

In another example, the double-layered patternable adhesive film may be formed by a method including the following operations:
forming a second adhesive film having a second adhesive layer on a second base film by applying a second adhesive composition, which contains (a) a thermosetting compound or alkali or an organic solvent developable thermosetting compound, (b) an alkali or organic solvent developable compound, (c) an organic solvent, and (d) at least one additive selected from the group consisting of a photocurable compound, a photoinitiator, a binder, a thermosetting agent, a thermosetting catalyst, a photoacid generator, and any combination thereof;
forming a first adhesive film having a first adhesive layer on a first base film by applying a first adhesive composition, which contains (e) a photocurable compound, (f) an organic solvent, and (g) at least one additive selected from the group consisting of a thermosetting compound, a thermosetting agent, a thermosetting catalyst, a binder, a photoinitiator, a photoacid generator, and any combination thereof; and
laminating the first adhesive film to the second adhesive film to face each other by contacting the exposed surfaces of the first adhesive film and the second adhesive film with pressing or pressing and heating.

In the second adhesive composition, the content of the thermosetting compound or developable thermosetting compound may be higher than that of the developable compound. The content of the thermosetting compound or developable thermosetting compound of the total content of the second adhesive composition may be 20 to 95 wt % or in a further example 30 to 95 wt % based on the weight of the solid components (i.e., excepting the organic solvent). Similarly, when a large amount of the thermosetting compound or developable thermosetting compound is added, the second adhesive layer can have excellent adhesion.

In the first adhesive composition, the content of the photocurable compound may be higher than that of the thermosetting compound. The content of the photocurable compound of the total content of the first adhesive composition may be 30 to 95 wt % based on the weight of the solid components (i.e., excepting the organic solvent). Similarly, when a large amount of the photocurable compound is added, the first adhesive layer can have excellent patternability.

The thermosetting compounds, developable thermosetting compounds, alkali or organic solvent developable compounds, photocurable compounds, and binders used in the second and first adhesive compositions are the same as those described above.

Hereinafter, other components will be described in detail.

### Organic Solvent

The adhesive composition may use a suitable organic solvent (b) or (e) to uniformly dissolve or disperse materials. For example, as the organic solvent, one or a combination of at least two selected from the group consisting of dimethyl formamide, dimethyl sulfoxide, toluene, benzene, xylene, methyl ethyl ketone, tetrahydrofuran, ethyl acetate, ethyl cellosolve, ethyl cellosolve acetate, dioxane, cyclohexanone, N-methyl pyrrolidone, and any combination thereof may be used.

### Thermosetting Agent

As the thermosetting agent, a phenol-based compound, aliphatic amine, alicyclic amine, aromatic polyamine, polyamide, aliphatic acid anhydride, alicyclic acid anhydride, aromatic acid anhydride, dicyandiamide, a boron trifluoride-amine complex, imidazole, tertiary amine, a phenol-based compound having at least two phenolic hydroxy groups in one molecule, or any combination thereof may be used.

The thermosetting agent may be a phenol-based compound having at least two phenolic hydroxy groups in one molecule, which can provide excellent developability in an organic or alkali solvent. Examples of the phenol-based compound having at least two phenolic hydroxy groups in one molecule may include a phenol novolac resin, a cresol novolac resin, a t-butyl phenol novolac resin, a xylene-modified novolac resin, a naphthol novolac resin, a trisphenol novolac resin, a tetrakisphenol novolac resin, a bisphenol A novolac resin, a poly-p-vinyl phenol resin, a phenol aralkyl resin, a trisphenol compound, and any combination thereof.

### Thermosetting Catalyst

The compositions contain thermosetting components, and thermosetting catalysts may be added as necessary. The thermosetting catalyst is provided to stimulate curing of a thermosetting resin, and may include, but is not limited to:
i. imidazole and imidazole derivatives such as 2-methylimidazole, 2-ethylimidazole, 2-ethyl-4-methylimidazole, 2-phenylimidazole, 4-phenylimidazole, 1-cyanoethyl-2-phenylimidazole, and 1-(2-cyanoethyl)-2-ethyl-4-methylimidazole;
ii. amine compounds such as dicyandiamide, benzyl dimethylamine, 4-(dimethyldiamino)-N,N-dimethylbenzylamine, 4-methoxy-N,N-dimethylbenzylamine, and 4-methyl-N,N-dimethylbenzylamine;
iii. hydrazine compounds such as adipic acid dihydrazide, and sebacic acid dihydrazide;
iv. phosphorous compounds such as triphenylphosphine;
v. borate compounds such as tetraphenylphosphonium tetraphenylborate, and 2-ethyl-4-methyl imidazole-tetraphenylborate; and any combination thereof.

The thermosetting catalyst may also catalyze thermal curing of an epoxy resin or oxetane compound, or stimulate a reaction of a carboxyl group with an epoxy group, and/or an oxetanyl group. The thermosetting catalyst may be one or a combination of at least two of the above-described examples.

The thermosetting catalyst may also be a S-triazine derivative of guanamine, acetoguanamine, benzoguanamine, melamine, 2,4-diamino-6-methacryloyloxyethyl-S-triazine, 2-vinyl-4,6-diamino-S-triazine, 2-vinyl-4,6-diamino-S-triazine-isocyanuric acid addition, 2,4-diamino-6-methacryloyloxyethyl-S-triazine-isocyanuric acid addition, or any combination thereof. This derivative may serve as a tackifier, and thus can be used with the thermosetting catalyst.

### Photoinitiator

The photoinitiator may have an absorption band of about 400 nm to form a high-fine pattern during exposure. The photoinitiator may include one or a combination of at least two selected from the group consisting of 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, methylbenzoxylformate, α,α-dimethoxy-α-phenyl acetophenone, 2-benzyl-2-(dimethylamino)-1-[4-(4-morpholinyl)phenyl]-1-butanone, 2-methyl-1-[4-(methylthio)phenyl]-2-(4-morpholinyl)-1-propanone, diphenyl(2,4,6-trimethylbenozoyl)-phosphine oxide, and phosphine oxide.

### Photoacid Generator

The photoacid generator is capable of curing some thermosetting resins such as an epoxy resin by generating acids through irradiation with light. As the photoacid generator, an aromatic iodonium or sulfonium salt are generally used. The photoacid generator may include one or a combination of at least two selected from the group consisting of di(t-butylphenyl)iodonium triflate, diphenyliodonium tetrakis(pentafluorophenyl)borate, diphenyliodonium hexafluorophosphate, diphenyliodonium hexafluoroantimonate, di(4-nonylphenyl)iodonium hexafluorophosphate, [4-(octyloxy)phenyl]phenyl iodonium hexafluoroantimonate, triphenylsulfonium triflate, triphenylsulfonium hexafluorophosphate, triphenylsulfonium hexafluoroantimonate, triphenylsulfonium tetrakis(pentafluorophenyl)borate, 4,4′-bis[diphenylsulfonium]diphenylsulfide, bis-hexafluorophosphate, 4,4′-bis[di(β-hydroxyethoxy) phenylsulfonium]diphenylsulfide bis-hexafluoroantimonate, 4,4′-bis[di(β-hydroxyethoxy)(phenylsulfonium)]diphenyl sulfide bishexafluorophosphate, 7-[di(p-tolyl)sulfonium]-2-isopropylthioxanthone hexafluorophosphate, 7-[di(p-tolyl)sulfonio-2-isopropylthioxanthone hexafluoroantimonate, 7-[di(p-tolyl)sulfonium]-2-isopropyl tetrakis(pentafluorophenyl)borate, phenylcarbonyl-4′-diphenylsulfonium diphenylsulfide hexafluorophosphate, phenylcarbonyl-4′-diphenylsulfonium diphenylsulfide hexafluoroantimonate, 4-tert-butylphenylcarbonyl-4′-diphenylsulfonium diphenylsulfide hexafluorophosphate, 4-tert-butylphenylcarbonyl-4′-diphenylsulfonium diphenylsulfide hexafluoroantimonate, 4-tert-butylphenylcarbonyl-4-diphenylsulfonium diphenylsulfide tetrakis(pentafluorophenyl)borate, diphenyl[4-(phenylthio)phenyl]sulfonium hexafluoroantimonate, and any combination thereof.

### Other Additives

The first or second adhesive composition may further include at least one additive selected from the group consisting of a filler, a coupling agent, a coloring agent, an ion absorbent, an antifoaming agent, a leveling agent, a thickening agent, a flame retardant, and any combination thereof. These additives are the same as described in 1(5).

### Film Formation

The first or second adhesive composition is applied to a uniform thickness to the base film 110 using a roll coater, a bar coater, a comber coater, a blade coater, a lip coater, a rod coater, a squeeze coater, a reverse coater, a transfer roll coater, a gravure coater, or a spray coater, and generally dried at a temperature of from 50 to 130° C. for 1 to 30 minutes, and in this way the adhesive film is formed.

A thickness of the coated layer is not particularly limited, and may be from 0.1 to 150 μm or in a further example 0.5 to 100 μm after drying. The coated layer is dried in a forced convention drying type using an infrared (“IR”) furnace, a hot plate, or a convection oven, for example, by countercurrent contacting hot wind made from a heat source in a drier with the layer by air heating through evaporation or blowing hot air on a support using a nozzle.

A delaminatable cover film (protective film) may be laminated on the adhesive layer to prevent dust from attaching to a surface of the adhesive layer after being laminated on the base film 110.

The delaminatable cover film may be a polyethylene film, a polytetrafluoroethylene film, a polypropylene film, or a surface-treated paper. To delaminate the cover film, the degree of adhesion between the adhesive layer and the base film 110 is larger than that between the adhesive layer and the cover film.

### III. Method of Forming Patternable Adhesive Layer

A method of forming a patternable adhesive layer on an adherend is provided.

According to an exemplary embodiment, a patternable adhesive layer may be formed by disposing the double-layered patternable adhesive film on an a surface of an adherend. Once the double-layered patternable adhesive film is formed in the structure of a base film, a second adhesive layer, and a first adhesive layer as described above, the base film may be removed from the adhesive film, and then the adhesive film may be adhered to the adherend. According to another exemplary embodiment, the patternable adhesive layer may be formed by applying the second adhesive composition, as described in 2, to form the second adhesive layer on a surface of the adherend, and applying the first adhesive composition, as described in 2, to form the first adhesive layer on a surface of the second adhesive layer.

According to the exemplary embodiments, patternable adhesive layers are formed on the adherend in a double-layered structure laminated in the order of adherend, the second adhesive layer and the first adhesive layer. In one example, the patterned adhesive layer may be formed by forming a pattern by exposure and development, and thermally compressing the patterned layer.

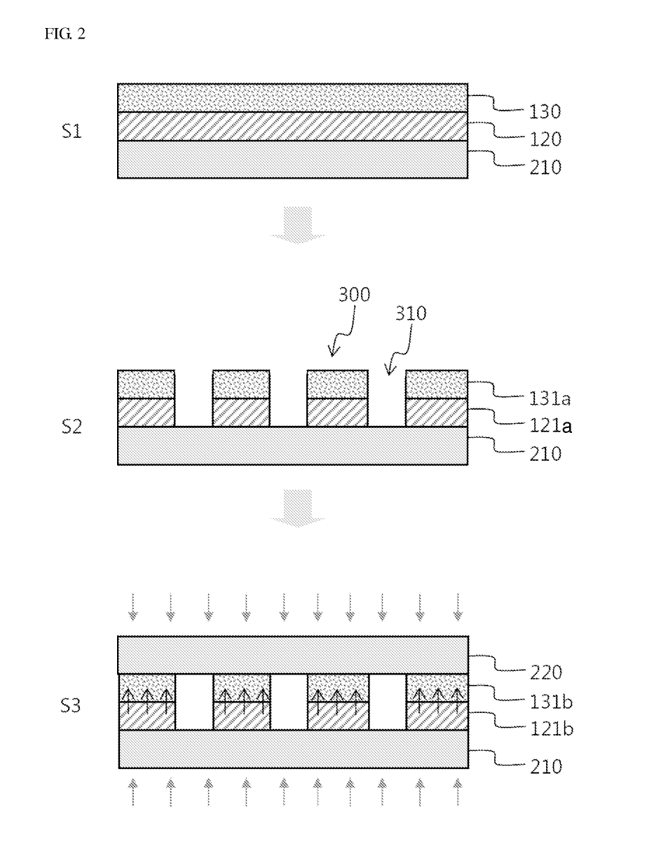

In FIG. 2, a process of forming the patternable adhesive layer is schematically illustrated. According to the method of forming the patternable adhesive layer described with reference to FIG. 2, the double-layered patternable adhesive layer is formed on a surface of an adherend 210 (S1), followed by forming a pattern by exposure and development (S2), and thermally compressing the patterned layer (S3).

According to one exemplary embodiment, the double-layered patternable adhesive layer may be formed by disposing the double-layered patternable adhesive film on the surface of the adherend 210 (S1), forming a pattern by exposure and development (S2), and thermally compressing the patterned layer (S3).

According to another exemplary embodiment, the first and second adhesive compositions described in 2 are individually provided and laminated twice on an adherend to form a patternable adhesive layer (S1). In detail, the second and first adhesive compositions are sequentially applied to the adherend 210 and then dried, thereby forming a second adhesive layer 120 on the surface of adherend 210 and a first adhesive layer 130 (S1) on a surface of second adhesive layer 120. Subsequently, a pattern is formed by exposure and development (S2), and the patterned layer is thermally compressed (S3).

As shown in FIG. 2, when two adherends 210 and 220, which are adhered to each other, are used, after the patterning (S2), another adherend 220 may be disposed on an exposed surface of the patterned layer where the exposed surface is in the plane of the adherend 210, and thermally compressed (S3). When a plurality of adherends are used, operations S1 through S3 may be repeated, or the formation of the adhesive layer (S1) and the patterning (S2) may be repeated, followed by performing the thermal compression (S3) in a final operation.

According to the above method, the second adhesive layer 120 or film having high adhesion is laminated on a surface of the adherend 210, followed by laminating the first adhesive layer 130 or film which can easily form a pattern on an exposed surface of the second adhesive layer 120, and thus both patternability and adhesion can be improved.

Here, since the patternability of the first adhesive layer 130 does not decrease after the development, it is easy to form a pattern. In addition, since the second adhesive layer 120 is disposed under the first adhesive layer 130 (i.e., sandwiched between the adherend 210 and the first adhesive layer 130), it has less chance to be in contact with the developing solution in the development. Thus, contact of the second adhesive layer 120 to a developer is limited, and loss of low molecular weight materials such as found in the thermosetting part is significantly reduced, compared to when only the second adhesive layer 120 is developed.

As a result, when the double-layered adhesive film is exposed and developed, it has better developability than when only the second adhesive layer is exposed and developed. Moreover, when the double-layered adhesive film is developed, a larger amount of the thermosetting part remains in the adhesive film than when only the first or second adhesive layer is used. In addition, through the thermal compression, the thermosetting part remaining in the second adhesive layer penetrates into the first adhesive layer 130, thereby providing excellent adhesion.

The adherend 210 or 220 is a body attached to another by an adhesive, and may include, but is not limited to, a printed circuit board (“PCB”), a polyimide film, a PET film, a glass substrate, a ceramic substrate, a semiconductor wafer, or a semiconductor array. The PCB includes every level (including Flame Retardant 4 epoxy (“FR-4”), and the like) of copper-clad laminated substrates using a paper-phenol resin, a paper-epoxy resin, a glass fabric-epoxy resin, a glass-polyimide resin, a glass fabric/felt-epoxy resin, a glass fabric/paper-epoxy resin, a synthetic fabric-epoxy resin, a complex material such as fluoride resin.poylethylene.polyphenyleneoxide (“PPO”).cyanate ester, or any combination thereof, in addition to a flexible PCB.

Specifically, in fabrication of a semiconductor package, the method of forming the patternable adhesive layer described herein may be applied.

### Formation of Adhesive Layer (S1)

There is no particular limitation in forming the first and second adhesive layers 130 and 120, for example, by disposing the double-layered patternable adhesive film on the adherend 210 or laminating sequentially the individual adhesive layers on the adherend (S1). For example, the compositions or film may be applied to or disposed on the adherend using a roll coater, a bar coater, a comber coater, a blade coater, a lip coater, a rod coater, a squeeze coater, a reverse coater, transfer roll coater, a gravure coater, a spray coater, or any combination of these application methods, and dried at a temperature of 50 to 130° C. for a time of 1 to 30 minutes.

### Patterning (S2)

In a negative-tone imaging method, the adhesive layer is exposed (by irradiation with active energy beams, i.e., actinic radiation as discussed hereinabove). The exposure may be performed in a contact or non-contact type, for example, by selectively irradiating the layer with active energy beams using a photomask having a pattern, or directly patterning the layer using, for example, a laser direct exposure system such as by interferometry or direct-write, or e-beam exposure. An exposed part 300 (a portion irradiated with the active energy beams) of the adhesive layer is cured by exposure.

Subsequently, a non-exposed part 310 is developed with a developing solution such as an organic solvent or alkali aqueous solution to form a pattern.

Additionally, the patterned layer may be heated to about 140 to 180° C. for thermal curing, or irradiated with the active energy beams and then thermally cured or thermally cured and then finally cured (main curing) by irradiation with the active energy beams to react the photocurable component with the thermosetting component, leading to forming of a cured adhesive layer having excellent characteristics such as for example cohesion, resistance to solder heat, resistance to chemicals, resistance to moisture, resistance to electroless gold plating, electric insulation, and the like.

The exposure system used in irradiation with the active energy beams may include an apparatus for irradiating with UV radiation at a wavelength of 350 to 450 nm, with a high pressure mercury lamp, an extra-high pressure mercury lamp, a metal halide lamp, or a mercury short arc lamp.

Alternatively, instead of the exposure system, a direct writing apparatus (e.g., a laser direct imaging apparatus configured to directly draw an image using laser according to computer-aided design (“CAD”) data provided by computer) may be used. Laser beams for the direct writing apparatus have a maximum wavelength of 350 to 410 nm, which may be generated as the emission wavelength of a gas laser, or solid-state laser. An exposure dose suitable for forming an image may generally be 20 to 1,000 mJ/cm² or 100 to 900 mJ/cm², which may vary depending on the thickness of a layer and the concentration of photoactive components.

The development may be performed by dipping, showering, spraying, puddling (static or dynamic), or brushing, and the developing solution used herein may include an organic solvent such as dimethylacetamide, N-methylpyrrolidone, 2-heptanone, cyclohexanone, propyleneglycol monomethylether acetate, propylene glycol monomethyl ether, ethyl lactate, or the like, or any combination thereof or an alkali aqueous solution such as potassium hydroxide, sodium hydroxide, sodium carbonate, potassium carbonate, sodium phosphate, sodium silicate, tetraalkylammonium hydroxide including tetramethylammonium hydroxide, ammonia, amines, or any combination thereof.

### Thermal Compression (S3)

The adhesive layers 120 and 130 are exposed and developed to have a pattern. Afterwards, the patterned layers 121a and 131a, respectively, are adhered to another adherend such a wafer or chip by thermal compression.

In the thermal compression (denoted by gray arrows above adherend 220 and below adherend 210 in FIG. 2, S3), a large amount of the thermosetting part remaining in the patterned second adhesive layer 121b penetrates into the patterned first adhesive layer 131b (denoted by black arrows pointing from patterned second adhesive layer 121b into patterned first adhesive layer 131b). As a result, the adhesion of the double-layered adhesive layer after the thermal compression is improved, compared to when only the first or second adhesive layer 130 or 120 is patterned and thermally compressed.

The thermal compression may be performed using a hot roll laminator operating at a temperature of 120 to 350° C. or in a further example 200 to 300° C. at a pressure of 0.1 to 10 kgf for a time of 1 second to 1 hour or in a further example, 5 seconds to 10 minutes.

### EXAMPLES

Exemplary embodiments will be described in further detail with reference to Preparation Examples, Examples, Comparative Examples and Experimental Examples. The following examples are merely to explain the exemplary embodiments, not to limit the exemplary embodiments.

### Preparation Example 1

### Preparation of First Adhesive Composition

30 parts by weight of an acrylic binder (ACA-230AA, Daicel Chemical), 52 parts by weight of a photocurable compound (ZFR-1401H, Nippon Kayaku), 3 parts by weight of a photocurable initiator, 1-hydroxy-cyclohexyl-phenyl-ketone (IRGACURE® 184 initiator, Ciba Specialty Chemical), 10 parts by weight of an o-cresol novolac-based developable thermosetting resin (EOCN-104S, Nippon Kayaku), 3 parts by weight of a phenol-based curing agent (HF-1M, Meiwa Plastic), 1 part by weight of a thermosetting catalyst, 2-ethyl-4-methyl imidazole (2E4MZ, Shikoku Chemical), and 1 part by weight of a photoacid generator, triarylsulfonium hexafluorophosphate salt were uniformly mixed in 50 parts by weight cyclohexanone, to prepare a first adhesive composition.

### Preparation Example 2

### Preparation of Second Adhesive Composition

A second adhesive composition was prepared by the same method as described in Preparation Example 1, except that composition and contents of components are as shown in Table 1 below.

### Preparation Example 3

### Preparation of First Adhesive Composition

A first adhesive composition was prepared by the same method as described in Preparation Example 1, except that composition and contents of components are as shown in Table 1 below.

### Preparation Example 4

### Preparation of Second Adhesive Composition

A second adhesive composition was prepared by the same method as described in Preparation Example 1, except that composition and contents of components are as shown in Table 1 below.

TABLE 1

| | | Preparation | Preparation | Preparation | Preparation |
|---|---|---|---|---|---|
| | Component | Example 1 | Example 2 | Example 3 | Example 4 |
| Component | Product Name | (pbw) | (pbw) | (pbw) | (pbw) |
| Binder part | ACA-230AA | 30 | 30 | 30 | 30 |
| Photocurable | ZFR-1401H | 52 | 0 | 40 | 15 |
| part | | | | | |
| Photoinitiator | IRGACURE ® | 3 | 3 | 3 | 3 |
| | 184 Initiator | | | | |
| Developable | EOCN-104S | 10 | 50 | 20 | 40 |
| thermosetting | | | | | |
| part | | | | | |
| Curing agent | HF-1M | 3 | 15 | 5 | 10 |
| Thermosetting | 2E4MZ | 1 | 1 | 1 | 1 |
| catalyst | | | | | |
| Photoacid | **TASHFP | 1 | 1 | 1 | 1 |
| generator | | | | | |

**TASHFP: Tiracylsulfonium hexafluorophosphate salts

### Example 1

### Patternable Adhesive Layer Using Double-Layered Patternable Adhesive Film

The second adhesive composition according to Preparation Example 2 was applied by doctor blade coating to a PET film whose surface was treated with silicon for release, and dried in a forced convection drying oven at 70° C. for 10 minutes, to form a second adhesive layer having a thickness of 20 μm.

Afterwards, the first adhesive composition according to Preparation Example 1 was applied by doctor blade coating to the exposed surface of the second adhesive layer, and dried in a forced convection drying oven at 70° C. for 10 minutes, thereby forming a first adhesive layer to a thickness of 20 μm. In this way, a double-layered patternable adhesive film was prepared.

The double-layered patternable adhesive film was laminated to a silicon wafer as a base wafer by removing the PET film from the second adhesive layer, applying the exposed surface of the second adhesive layer to the base wafer by dry transfer, and laminating at 70° C. to dispose the second adhesive layer on a base wafer, thereby forming a patternable adhesive layer.

### Example 2

### Patternable Adhesive Layer Using Double-Layered Patternable Adhesive Film

A double-layered patternable adhesive film and a patternable adhesive layer were formed by the same method as described in Example 1, except that a second adhesive layer was formed using the second adhesive composition according to Preparation Example 4 and a first adhesive layer was formed using the first adhesive composition according to Preparation Example 3.

### Example 3

### Patternable Adhesive Layer Using Double-Layered Patternable Adhesive Film

A double-layered patternable adhesive film and a patternable adhesive layer formed by applying the double-layered patternable adhesive film to the base wafer were formed by the same method as described in Example 1, except that a second adhesive layer of the double-layered patternable adhesive film was formed using the second adhesive composition according to Preparation Example 4 and a first adhesive layer was formed using the first adhesive composition according to Preparation Example 1.

### Example 4

### Two Adhesive Compositions-Applied Patternable Adhesive Layer

The second adhesive composition according to Preparation Example 2 was directly applied to a base wafer (followed by removal of the PET film) without forming a double-layered patternable adhesive film, and dried at 70° C. for 10 minutes, thereby forming a second adhesive layer to a thickness of 20 μm.

Afterwards, the first adhesive composition according to Preparation Example 1 was applied to the exposed surface of the second adhesive layer (followed by removal of the PET film), and dried at 70° C. for 10 minutes, thereby forming a first adhesive layer to a thickness of 20 μm. Thus, a patternable adhesive layer was prepared.

### Comparative Example 1

The first adhesive composition according to Preparation Example 1 was applied to the same PET film whose surface was treated with silicon for release as used in Example 1, and dried in a forced convection drying oven at 85° C. for 20 minutes, thereby forming a single-layered adhesive film to a thickness of 30 μm.

The single-layered adhesive film was laminated as in Example 1 to a silicon wafer as a base wafer at 70° C., thereby forming a single-layered patternable adhesive layer.

### Comparative Example 2

A single-layered adhesive film and a single-layered patternable adhesive layer were formed by the same method as described in Comparative Example 1, except that the second adhesive composition according to Preparation Example 2 was used instead of the first adhesive composition according to Preparation Example 1.

### Comparative Example 3

A single-layered adhesive film and a single-layered patternable adhesive layer were formed by the same method as described in Comparative Example 1, except that the first adhesive composition according to Preparation Example 3 was used instead of the first adhesive composition according to Preparation Example 1.

### Comparative Example 4

A single-layered adhesive film and a single-layered patternable adhesive layer were formed by the same method as described in Comparative Example 1, except that the second adhesive composition according to Preparation Example 4 was used instead of the first adhesive composition according to Preparation Example 1.

### Comparative Example 5

A double-layered adhesive film and a double-layered patternable adhesive layer were formed by the same method as described in Example 1, except that a second adhesive layer was formed using the first adhesive composition according to Preparation Example 1, and a first adhesive layer was formed using the second adhesive composition according to Preparation Example 2.

The compositions for the respective layers and the methods of forming the adhesive layers used in Examples 1 through 4 and Comparative Examples 1 through 5 are shown in Table 2 below.

TABLE 2

| | First Adhesive Layer | Second Adhesive Layer | Method of Forming Adhesive Layers |
|---|---|---|---|
| Example 1 | Preparation Example 1 | Preparation Example 2 | Applying double-layered patternable |
| | | | adhesive film |
| Example 2 | Preparation Example 3 | Preparation Example 4 | Applying double-layered patternable |
| | | | adhesive film |
| Example 3 | Preparation Example 1 | Preparation Example 4 | Applying double-layered patternable |
| | | | adhesive film |
| Example 4 | Preparation Example 1 | Preparation Example 2 | Sequentially applying adhesive |
| | | | compositions |
| Comparative | Preparation Example 1 | — | Applying single-layered adhesive |
| Example 1 | | | film |
| Comparative | Preparation Example 2 | — | Applying single-layered adhesive |
| Example 2 | | | film |
| Comparative | Preparation Example 3 | — | Applying single-layered adhesive |
| Example 3 | | | film |
| Comparative | Preparation Example 4 | — | Applying single-layered adhesive |
| Example 4 | | | film |
| Comparative | Preparation Example 2 | Preparation Example 1 | Applying double-layered patternable |
| Example 5 | | | adhesive film |

### Experimental Example 1

### Evaluation of Patternability

The adhesive layers laminated on the wafers according to Comparative Examples 1 through 5 and Examples 1 through 4 were exposed using a high-precision parallel light exposure system (USHIO, HB-25103BY-C) at an exposure dose of 1,000 mJ/cm², and post exposure-baked at about 85° C. for 15 minutes.

The exposed layers were developed with a propyleneglycol monomethylether acetate solution using a spin coater at 1,500 rpm for 30 seconds, and cleaned with isopropyl alcohol twice at 1,000 rpm for 15 seconds to observe patterns.

The developed films on the wafers were analyzed using a scanning electron microscope (“SEM”) to assess developability of the adhesive films. When the exact pattern exposed is formed after developing, it is represented by \textcircled{∘}, when the pattern is dull (i.e., incompletely formed and/or insufficiently cleared), it is represented by ◯, and when no pattern is observed, it is represented by ×. The results are shown in Table 3.

### Experimental Example 2

### Evaluation of Die Shear Strength

The adhesive layers laminated on the wafers according to Comparative Examples 1 through 5 and Examples 1 through 3 were cut to leave only adhesive portions. The cut portions were exposed using a high-precision parallel light exposure system at 1,000 mJ/cm², and then patterning was simulated under the same development and cleaning conditions as used for Experimental Example 1. Afterwards, a lower chip cut into a size of 10 mm×10 mm was thermally compressed on a hot plate at a temperature of 250° C. at a pressure of 1 kgf for 10 seconds, and cured at 175° C. for 2 hours.

The die shear strength of an upper chip was measured twice with a tensile speed of 10 μm/sec at 25 and 250° C., and the results are shown in Table 3 below.

TABLE 3

| | | *C. Example1 | C. Example2 | C. Example3 | C. Example4 | C. Example5 | Example1 | Example2 | Example3 | Example4 |
|---|---|---|---|---|---|---|---|---|---|---|
| Patternability | | ⊚ | ◯ | ⊚ | ◯ | X | ⊚ | ⊚ | ⊚ | ⊚ |
| Die Shear | 25° C. | 4.5 | 9.1 | 6.3 | 8.3 | 20.5 | 18.1 | 16.5 | 18.2 | 17.2 |
| Strength | 250° C. | 0.31 | 0.52 | 0.44 | 0.45 | 0.85 | 3.5 | 3.1 | 2.5 | 2.2 |
| (Kgf/chip) | | | | | | | | | | |

⊚: when the exact pattern is formed/
◯: when the pattern is dull/
X: when no pattern is formed
*C. Example: Comparative Example

It can be seen from Table 3 that the patternable adhesive layers formed using the double-layered patternable adhesive films according to Examples 1 through 3, and the patternable adhesive layer formed by sequentially applying the second adhesive composition and the first adhesive composition (Example 4) have excellent patternability and adhesion, compared to the adhesive layers according to Comparative Examples.

While exemplary embodiments have been disclosed herein, it should be understood that other variations may be possible. Such variations are not to be regarded as a departure from the spirit and scope of exemplary embodiments, and all such modifications as would be obvious to one skilled in the art are intended to be included within the scope of the following claims

What is claimed is:

1. A double-layered patternable adhesive film, comprising:
a first adhesive layer including a photocurable part containing a photocurable component (A); and
a second adhesive layer disposed on a surface of the first adhesive layer and including a second thermosetting part comprising a thermosetting component (B), and a developable part comprising an alkali or organic solvent developable component (C).

2. The film according to claim 1, wherein the first adhesive layer is formed to have an exposed surface, and the second adhesive layer is formed to interface with an adherend.

3. The film according to claim 1, wherein the first adhesive layer further includes a first thermosetting part containing a thermosetting component (B), and the photocurable part is included in a higher content than the first thermosetting part.

4. The film according to claim 3, wherein the content of the photocurable part is from about 30 wt % to about 95 wt % of the total weight of the first adhesive layer.

5. The film according to claim 1, wherein, in the second adhesive layer, the second thermosetting part is included in a higher amount than the developable part.

6. The film according to claim 5, wherein the content of the second thermosetting part is from about 20 wt % to about 95 wt % of the total weight of the second adhesive layer.

7. The film according to claim 3, wherein the first adhesive layer includes a photocurable part containing a photocurable component (A) and an alkali or organic solvent developable component (C); a first thermosetting part containing a thermosetting component (B); and a binder part.

8. The film according to claim 1, wherein the second adhesive layer includes a second thermosetting part containing a thermosetting component (B); a developable part containing an alkali or organic solvent developable component (C) and a photocurable component (A); and a binder part.

9. The film according to claim 7, wherein the photocurable part containing the photocurable component (A) and the alkali or organic solvent developable component (C) includes a (meth)acrylate-based compound having an ethylenic unsaturated double bond.

10. The film according to claim 8, wherein the second adhesive layer includes an alkali or organic solvent developable thermosetting compound in which the second thermosetting part and the developable part are included in the form of an incorporated compound.

11. The film according to claim 10, wherein the alkali or organic solvent developable thermosetting compound is a multifunctional epoxy resin.

12. The film according to claim 8, wherein, in the second adhesive layer, the second thermosetting part and the developable part are included in the form of separate compounds, the developable part including a (meth)acrylate-based compound having a carboxyl or hydroxy group and an ethylenic unsaturated double bond.

13. The film according to claim 7, wherein the binder part includes a (meth)acrylate-based compound having a carboxyl or hydroxy group and an ethylenic unsaturated double bond.

14. The film according to claim 8, wherein the binder part includes a (meth)acrylate-based compound having a carboxyl or hydroxy group and an ethylenic unsaturated double bond.

15. The film according to claim 1, wherein the first or second adhesive layer further includes at least one additive selected from the group consisting of a filler, a coupling agent, a coloring agent, an ion adsorbent, an antifoaming agent, a leveling agent, a thickening agent, a flame retardant, and any combination thereof.

16. A method of forming a double-layered patternable adhesive film according to claim 1, comprising:
forming a second adhesive layer, on a surface of a base film, by applying a second adhesive composition including (a) a thermosetting compound or an alkali or organic solvent developable thermosetting compound, (b) an alkali or organic solvent developable compound, (c) an organic solvent, and (d) at least one additive selected from the group consisting of a photocurable compound, a photoinitiator, a binder, a thermosetting agent, a thermosetting catalyst, a photoacid generator, and any combination thereof; and
forming a first adhesive layer, on a surface of the second adhesive layer, by applying a first adhesive composition including (e) a photocurable compound, (f) an organic solvent, and (g) at least one additive selected from the group consisting of a thermosetting compound, a thermosetting agent, a thermosetting catalyst, a binder, a photoinitiator, a photoacid generator, and any combination thereof.

17. The method according to claim 16, wherein the first or second adhesive composition further includes (h) at least one additive selected from the group consisting of a filler, a coupling agent, a coloring agent, an ion adsorbent, an antifoaming agent, a leveling agent, a thickening agent, a flame retardant, and any combination thereof.

18. A method of forming a patternable adhesive layer, comprising:
placing a double-layered patternable adhesive film according to claim 1 on a surface of an adherend;
forming a pattern by exposure and development; and
performing thermal compression.

19. A method of forming a patternable adhesive layer, comprising:
forming a second adhesive layer, on a surface of an adherend, by applying a second adhesive composition including (a) a thermosetting compound or an alkali or organic solvent developable thermosetting compound, (b) an alkali or organic solvent developable compound, (c) an organic solvent, and (d) at least one additive selected from the group consisting of a photocurable compound, a photoinitiator, a binder, a thermosetting agent, a thermosetting catalyst, a photoacid generator, and any combination thereof;
forming a first adhesive layer, on a surface of the second adhesive layer, by applying a first adhesive composition including (e) a photocurable compound, (f) an organic solvent, and (g) at least one additive selected from the group consisting of a thermosetting compound, a thermosetting agent, a thermosetting catalyst, a binder, a photoinitiator, a photoacid generator, and any combination thereof;
forming a pattern by exposure and development; and
performing thermal compression.

20. The method according to claim 17, wherein the adherend is selected from the group consisting of a printed circuit board (PCB), a polyimide film, a polyethylene terephthalate (PET) film, a glass substrate, a ceramic substrate, a wafer, a semiconductor array, a semiconductor chip, and any combination thereof.
